(19) United States
(12) Patent Application Publication
(10) Pub. No.: US 2004/0168769 A1
(43) Pub. Date: Sep. 2, 2004

(54) Plasma processing equipment and plasma processing method

(76) Inventors: Takaaki Matsuoka, Minato-ku (JP); Satoru Kawakami, Nirasaki-shi (JP); Katsuhiko Iwabuchi, Tsukui-gun (JP)

Correspondence Address: CROWELL & MORING LLP, INTELLECTUAL PROPERTY GROUP, P.O. BOX 14300, WASHINGTON, DC, 20044-4300, US

(21) Appl. No.: 10/483,185

(22) PCT Filed: May 9, 2003
(86) PCT No.: PCT/JP03/05851

(30) Foreign Application Priority Data
May 10, 2002 (JP) 20021-136188

(51) Int. Cl. H01L 21/306

(52) U.S. Cl. 156/345.33

(57) ABSTRACT

A plasma processing apparatus, comprising: at least, a processing chamber for plasma-processing an object to be processed; gas supply means for supplying a gas into the processing chamber; and high-frequency supplying means for forming the gas into a plasma state. The gas supply means has at least one gas introduction pipe, and the tip of the gas introduction pipe is placed in a position in the processing chamber, which is capable of preferred control of the gas dissociation. There are provided a plasma processing apparatus and a plasma processing method which can improve the uniformity in the gas which has been supplied into the processing chamber.

### TECHNICAL FIELD

The present invention relates to a plasma processing apparatus which is suitably usable when an object to be processed (such as base material (or substrate) for an electronic device) is subjected to a plasma treatment for the purpose of manufacturing an electronic device, etc. More specifically, the present invention relates to a plasma processing apparatus and a plasma processing method which can provide an uniformity in the composition and/or density of a gas to be supplied to the plasma processing, while controlling the state of the gas dissociation based on the plasma.

### BACKGROUND ART

In general, the plasma processing apparatus according to the present invention is widely applicable to the plasma processing of an object to be processed (e.g., materials for electronic devices such as semiconductors or semiconductor devices, and liquid crystal devices). For the purpose of convenience of explanation, however, the background art relating to the semiconductor devices will be described in the following.

In recent years, as the semiconductor devices are caused to have a higher density and a finer structure or configuration, in the processes for manufacturing these electronic devices, there has been increased the number of cases using a plasma processing apparatus for the purpose of conducting various kinds of processing or treatments such as film formation, etching, and ashing. The use of the plasma processing is generally advantageous such that high-precision process control is facilitated.

For example, in the case of a plasma processing apparatus in the prior art, when high-frequency supplying means (for example, high-frequency antenna) is disposed in the central part of the plasma processing chamber thereof, it is usual that the gas introduction pipe is disposed in a peripheral portion of the plasma processing chamber, i.e., in a position which is remote from the high-frequency supplying means so as to provide a distance therebetween as long as possible.

JP-A (Unexamined Japanese Patent Publication; KOKAI) No. 9-63793 discloses a plasma processing apparatus wherein a planar (or flat-type) antenna member is used, and a raw material gas-introducing member is disposed in the central part of an antenna-covering member.

### DISCLOSURE OF INVENTION

An object of the present invention is to provide a plasma processing apparatus and a plasma processing method which can solve the above-mentioned problem encountered in the prior art.

Another object of the present invention is to provide a plasma processing apparatus and a plasma processing method which can enhance the uniformity in a gas which has been supplied to the plasma processing.

As a result of earnest study, the present inventors have found that the control of a gas dissociative state is extremely important in the case of plasma processing. As a result of further study, the present inventors have also found that it is extremely effective for controlling the gas dissociative state to dispose a gas introduction pipe in the neighborhood of the high-frequency supplying means so as to provide a specific positional relationship with the plasma processing chamber.

The plasma processing apparatus according to the present invention is based on the above discovery, and comprises: at least, a processing chamber for plasma-processing an object to be processed; gas supply means for supplying a gas into the processing chamber; and high-frequency supplying means for forming the gas into a plasma state; wherein the gas supply means has at least one gas introduction pipe, the tip of the gas introduction pipe is placed in a position so that the tip is projected from the inner wall of the processing chamber facing the object to be processed, toward the interior of the processing chamber.

The present invention also provides a plasma processing method, wherein an object to be processed which is placed in a processing chamber is subjected to plasma processing by utilizing plasma based on a gas which has been supplied into the processing chamber; the gas being supplied into the processing chamber from a gas introduction pipe; the tip of the gas introduction pipe being projected from the inner wall of the processing chamber facing the object to be processed, toward the interior of the processing chamber.

In view of the control of the gas dissociative state based on plasma processing, the plasma processing apparatus according to the present invention having the above structure can easily supply a gas to a position (or site) suitable for the gas dissociative state control, as compared with the above-mentioned plasma processing apparatus as described in JP-A 9-63793.

### BRIEF DESCRIPTION OF DRAWINGS

FIG. 1 is a schematic sectional view showing an example of the representative embodiment of the plasma processing apparatus according to the present invention.

FIG. 2 is a partial schematic sectional view showing an example of the gas introduction portion which is usable for the plasma processing apparatus according to the present invention.

FIG. 3 is a block diagram showing an example of the structure of a thermoregulator which is usable for the plasma processing apparatus according to the present invention.

FIG. 4 is a schematic view showing an example of the structure of a gas supply ring which is usable for the plasma processing apparatus according to the present invention.

FIG. 5 is a schematic view showing an example of the structure of the plane antenna member which is usable for the plasma processing apparatus according to the present invention.

FIG. 6 is a graph showing an example of the relationship between the electron temperature of plasma and the distance from a dielectric plate, which is usable for the plasma processing apparatus according to the present invention.

FIG. 7 is a schematic sectional view showing another example of the structure of gas supply means which is usable for the plasma processing apparatus according to the present invention.

FIG. 8 is a schematic plan view showing an example of structure of a gas outlet constituting the gas supply means which is usable for the plasma processing apparatus according to the present invention.

FIG. 9 is a schematic plan view showing an example of the structure of a flow channel or flow path member (or frame) which is usable in the gas supply means according to the present invention.

FIG. 10 is a schematic perspective view showing an example of the actual arrangement of the flow channel member (frame).

FIG. 11 is a schematic sectional view showing an example of the structure of the gas introduction pipe which is filled with balls, which is usable in the gas supply means according to the present invention.

FIG. 12 is a schematic sectional view showing an example of the gas supply method which is usable in the gas supply means according to the present invention.

FIGS. 13(a) and 13(b) are a schematic sectional view and a schematic plan view, respectively, showing another example of the structure of the gas introduction pipe which is usable in the gas supply means according to the present invention.

FIGS. 14(a) and 14(b) are schematic sectional views and a schematic plan view, respectively, showing another example of the structure of the gas introduction pipe which is usable in the gas supply means according to the present invention.

FIG. 15 is a schematic sectional view showing another example of the structure of the gas introduction pipe which is usable in the gas supply means according to the present invention.

FIGS. 16(a) and 16(b) are schematic sectional views and a schematic plan view, respectively, showing another example of the structure of the gas introduction pipe which is usable in the gas supply means according to the present invention.

FIGS. 17(a) and 17(b) are schematic sectional views and a schematic plan view, respectively, showing a further example of the structure of the gas introduction pipe which is usable in the gas supply means according to the present invention.

FIG. 18 is a schematic perspective view showing an embodiment of the arrangement of the waveguide, coaxial tube (mode converter) and central conductor for introducing a process gas, which are usable in the present invention.

FIG. 19 is a schematic sectional view showing another example of the arrangement of the first, second and third flow channel members which are usable in the present invention.

### BEST MODE FOR CARRYING OUT THE INVENTION

Hereinbelow, the present invention will be described in detail with reference to the accompanying drawings as desired. In the following description, “%” and “part(s)” representing a quantitative proportion or ratio are those based on mass, unless otherwise specifically noted.

(Plasma Processing Apparatus)

The plasma processing apparatus according to the present invention comprises: a processing chamber for plasma-processing therein an object to be processed, gas supplying means for introducing a gas into the processing chamber, and high-frequency supplying means for converting (or forming) the gas into a plasma sate. This gas supply means has at least one gas introduction pipe, and the tip of the gas introduction pipe is disposed in a position so that the gas introduction pipe is projected into the processing chamber from the inner wall of the processing chamber which is disposed opposite to an object to be processed.

(Diffusion Plasma Region)

In the present invention, the “diffusion plasma region” refers to a region of the plasma wherein an excessive dissociation of a reactant gas is not substantially caused.

(Neighborhood of Central Part of Processing Chamber)

In the present invention, it is preferred that the tip of at least one gas introduction pipe is disposed in the neighborhood of the central part of the processing chamber, in view of the uniformity in the process gas to be introduced into the plasma processing chamber (e.g., the uniformity in the gas concentration and/or gas composition).

(One Embodiment of Plasma Processing Apparatus)

Hereinbelow, an example of the microwave plasma processing apparatus 100 according to the present invention will be described with reference to accompanying drawings. In the description appearing hereinafter, in principle, the same reference numeral denotes the same or corresponding member or portion in the respective figures.

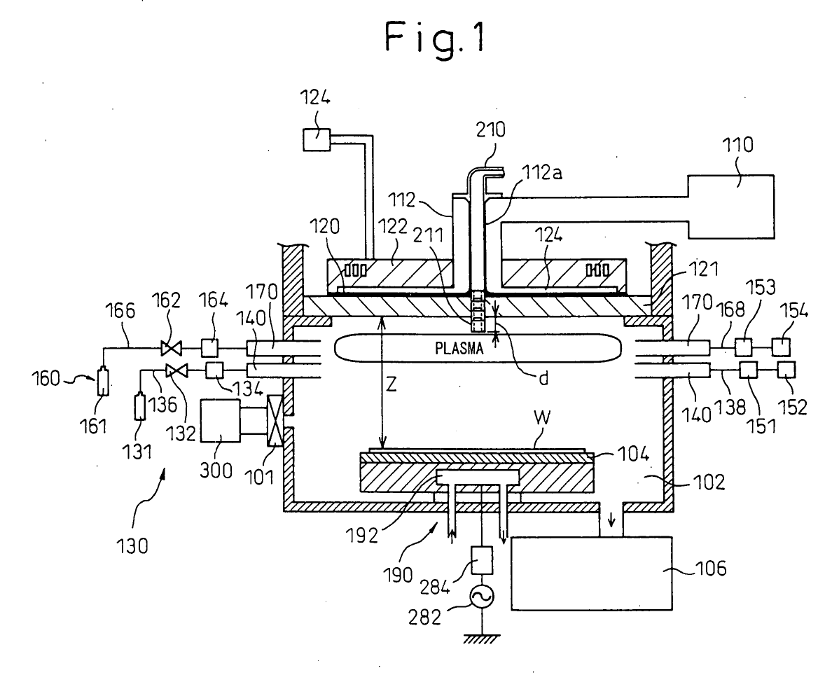

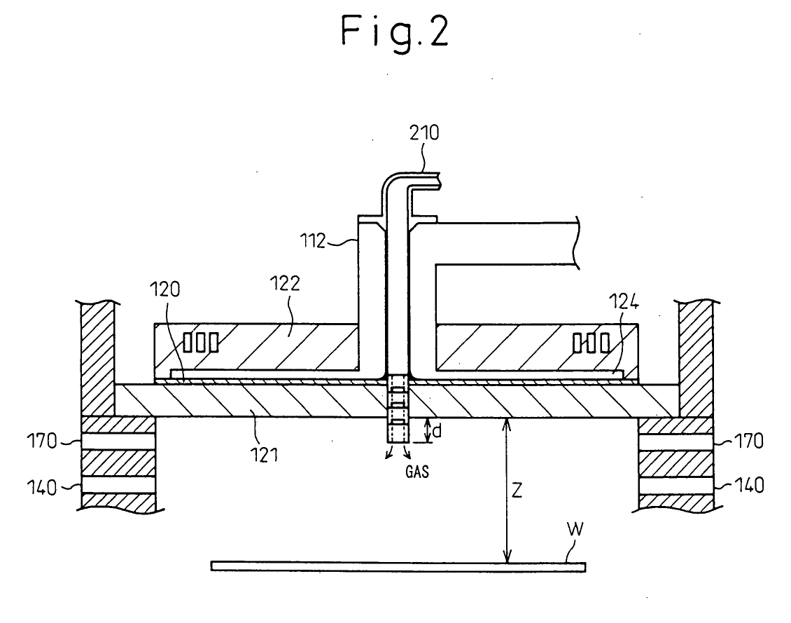

FIG. 1 is a schematic sectional view showing a representative structure of a microwave plasma processing apparatus in the vertical direction according to the present invention. FIG. 2 is an enlarged schematic sectional view showing a microwave/gas introduction portion of FIG. 1.

Referring to FIG. 1 and FIG. 2, the microwave plasma processing apparatus 100 in this embodiment has a gate valve 101 which is in communication with a cluster tool (not shown); a processing chamber 102 capable of accommodating a susceptor 104 on which an object W to be processed such as semiconductor wafer substrate (or base material) or LCD (liquid crystal device) substrate is to be placed; a high vacuum pump 106 connected to the processing chamber 102; a microwave source 110; an antenna member 120; and a first gas supply system 130 and a second gas supply system 160. In this figure, the control system for the plasma processing apparatus 100 is not shown.

In the microwave plasma processing apparatus 100 in this embodiment, a third gas supply system 210 is disposed in the central conductor 112a of a mode converter 112. In addition, as described hereinbelow, it is also possible to supply the gas which is required for the plasma processing only from the third gas supply system 210 in the present invention (in other words, it is possible to omit the first gas supply system 130 and the second gas supply system 160).

In the microwave plasma processing apparatus 100 in this embodiment, the nozzle 211 which is a gas supply port from the third gas supply system 210, is projected from insulation material 121 into the processing chamber 102 so as to provide a height “d”. In this embodiment, the height d corresponds to the position in the processing chamber which provides a suitable gas dissociative state. In this way, when the nozzle 211 is disposed so that it is projected into the processing chamber 102, it is possible to uniformize the composition and/or density of the gas to be supplied into the processing chamber 102, while enabling suitable control of the gas dissociation. Therefore, it is possible to uniformize the plasma processing (such as film formation, etching and cleaning) based on the gas. The effect of such uniformization of the plasma processing is remarkable, particularly when a wafer having a large diameter is used.

Referring again to FIG. 1, the structure or constitution of the plasma processing apparatus 100 in this embodiment will be described.

In the processing chamber 102, the side wall and the bottom thereof is constituted by a conductor such as aluminum. In this embodiment, the processing chamber 102 has, e.g., a cylindrical shape as shown in FIG. 1. However, the section of the processing chamber 102 (in the vertical direction) is not limited to a rectangular shape, but the section may also be another shape such as those having a convex shape with a curved or rounded portion. In the processing chamber 102, the susceptor 104 is placed, and the object W to be processed is supported on the susceptor 104. In addition, in FIG. 1, for the convenience of illustration, an electrostatic chuck or clamp mechanism for fixing the object W to be processed is omitted.

The susceptor 104 controls the temperature of the object W to be processed in the processing chamber 102. The temperature of the susceptor 104 is regulated to a predetermined temperature range by a thermoregulator 190.

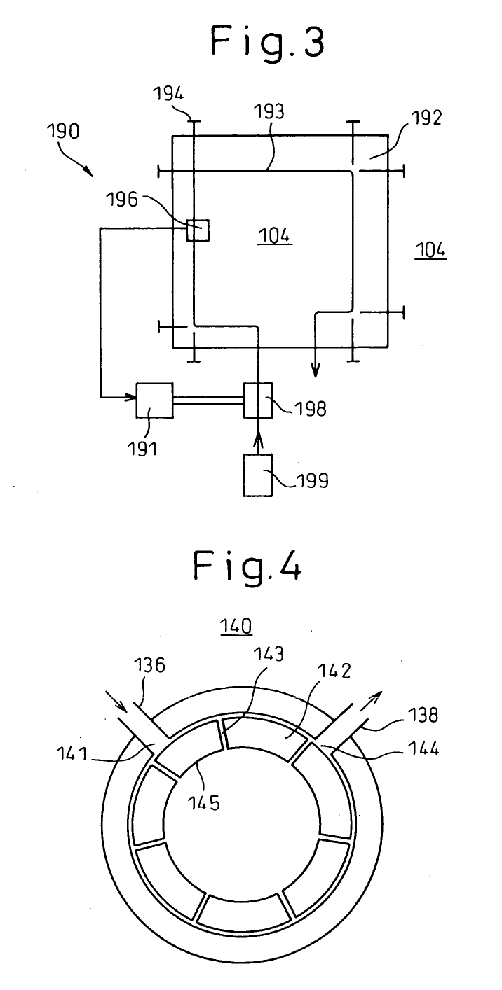

As shown in FIG. 3, the thermoregulator 190 has a controller 191, a cooling jacket 192, a sealing member 194, a temperature sensor 196, and a heater device 198. The thermoregulator 190 is supplied with cooling water from a water source 199 such as waterworks. FIG. 3 is a block diagram showing the detailed structure of the thermoregulator 190 as shown in FIG. 1. The controller 191 controls the temperature of the susceptor 104 and the object W to be processed so that they are within a predetermined temperature range. In view of easy control, it is preferred that the temperature of the cooling water supplied from the water source 199 is constant.

If the controller 191 can conduct the temperature control so as to provide an appropriate high temperature (e.g., about 450° C.) in the case of a film formation processes such as CVD (chemical vapor deposition), or so as to provide an appropriate low temperature (e.g., at lest 80° C. or less) in the case of an etching process. In any case, the temperature of the object W to be processed is set so that water content as an impurity does not attach to the object W to be processed.

The cooling jacket 192 flows cooling water to cool the object W to be processed at the time of the plasma processing. For example, a material such as stainless steel which has a good thermal conductivity, and enables easy formation of the flow channel 193 may be selected for the cooling jacket 192. The flow channel 193 may be formed, e.g., by forming longitudinal and lateral through-holes (or openings) in the cooling jacket 192 having a rectangular shape, and driving a sealing member 194 such as screw into the through-hole. Of course, regardless of FIG. 3, the cooling jacket 192 and the flow channel 193 may have an arbitrary shape. Instead of cooling water, it is of course possible to use another kind of coolant (such as alcohol, Garden, and Freon). As the temperature sensor 196, it is possible to use a well-known sensor such as PTC (positive temperature coefficient) thermistor, infrared sensor, and thermo-couple. The temperature sensor 196 may be connected to the flow channel 193, but the temperature sensor 196 need not to be connected to the flow channel 193.

For example, the heater device 198 is constituted by heater wires which are wound around the waterworks pipe connected to the flow channel 193 of the cooling jacket 192. The temperature of the water flowing in the flow channel 193 of the cooling jacket 192 can be regulated by controlling the strength of an electric current flowing through the heater wire. The cooling jacket 192 has a high thermal conductivity, and therefore it can be controlled at a temperature which is almost the same as the temperature of the water flowing through the flow channel 193.

Referring to FIG. 1, the susceptor 104 is constituted so that it is vertically movable (i.e., movable in the up and down direction) in the processing chamber 102. The vertical motion mechanism for the susceptor 104 comprises a vertically movable member, bellows, a vertical motion device, etc. Any kind of well-known structures in this technical field is applicable to the vertical motion mechanism. For example, the susceptor 104 is moved up and down by the vertical motion device between the home position and the process position therefor. The susceptor 104 is disposed in the home position at the off-time and the waiting time of the plasma processing apparatus 100. In the home position, the susceptor 104 transfers (or receives and deliver) the object W to be processed, from the cluster tool (not shown) or to the cluster tool through the gate valve 101. However, optionally, it is also possible to set a transfer position for the susceptor 104 so that the susceptor 104 may be in communication with the gate valve. The vertical motion distance for the susceptor 104 can be controlled by the controller of the vertical motion device (not shown), or the controller of the plasma processing apparatus 100, and the vertical motion distance for the susceptor 104 can be observed visually from a viewport (not shown).

In general, the susceptor 104 is connected to a lifter pin vertical motion mechanism (not shown). The lifter pin vertical motion mechanism comprises a vertically movable member, bellows, an vertical motion device, etc. Any kind of well-known structures in this technical field is applicable to the lifter pin vertical motion mechanism. The vertical motion device comprises, e.g., aluminum, and may be connected, e.g., to three lifter pins which are disposed at the apexes of an equilateral triangular shape and are extended in the direction which is perpendicular to the equilateral triangular shape. The lifter pins can penetrate the inside of the susceptor 104 so that they can support the object W to be processed so as to move up and down the object W to be processed, on or above the susceptor 104. The object W to be processed is moved vertically when the object W to be processed is introduced from the cluster tool (not shown) into the processing chamber 102, and when the object W to be processed after the processing is delivered to the cluster tool (not shown). The vertical motion device may be constituted so that it permits the vertical motion of the lifter pin, only when the susceptor 104 is in a predetermined position (e.g., home position). In addition, the vertical motion distance for the lifter pin can be controlled by the controller of the vertical motion device (not shown), or the controller of the plasma processing apparatus 100, and the vertical motion distance for the lifter pin can also be observed visually from a viewport (not shown).

The susceptor 104 may have a baffle plate (or straightening vane or plate), as desired. The baffle plate may be moved up and down together with the susceptor 104. Alternatively, the baffle plate may be constituted so that it may be engaged with the susceptor 104 which has been moved to the process position. The baffle plate has a function of separating the processing space wherein the object W to be processed is present, from the exhaust space below the processing space, so as to mainly ensure an electric potential in the processing space (i.e., to ensure the microwave in the processing space), and to maintain the degree of vacuum (e.g., at 6666 mPa). For example, The baffle plate is made of pure aluminum, and has a hollow disk shape. For example, the baffle plate has a thickness of 2 mm, and has a large number of random holes having a diameter of about 2 mm (e.g., having an aperture ratio (or open area ratio) of 50% or more). In addition, the baffle plate may optionally have a mesh structure. As desired, the baffle plate may also have a function of preventing the backflow from the exhaust space to the processing space, and may have a function of providing a differential pressure between the processing space and the exhaust space.

The susceptor 104 is connected to a high frequency power source 282 for providing a bias and to a matching box (matching circuit) 284, and these parts constitute an ion plating in combination with the antenna member 120. The high frequency power source 282 for providing a bias applies a negative DC bias (e.g., a high frequency of 13.56 MHz) to the object W to be processed. The matching box 284 prevents the influence of the stray inductance, electrode floating (or stray) capacitance, etc., in the processing chamber 102. The matching box 284 can provide the matching, e.g., by using a variable capacitor disposed in series or in parallel with respect to the load. As a result, the ions are accelerated toward the object W to be processed by the bias voltage, so as to promote the processing by the ions. The ion energy is determined by the bias voltage and the bias voltage can be controlled by the high-frequency power. The frequency to be applied from the power supply 283 can be regulated by the slit 120a of the plane antenna member 120.

The inside of the processing chamber 102 can be maintained so as to provide a predetermined reduced pressure, or a vacuum-sealed space by the high vacuum pump 106. The high vacuum pump 106 uniformly evacuates the processing chamber 102, and uniformly keep the plasma density so as to prevent a partial change in the processing depth of the object W to be processed due to partial concentration of the plasma density. In FIG. 1, one high vacuum pump 106 is provided in the processing chamber 102, but the position and number of the high vacuum pump 106 are only exemplified in FIG. 1. The high vacuum pump 106 is constituted, e.g., by a turbo-molecular pump (TMP), and it is connected to the processing chamber 102 through a pressure regulation valve (not shown). The pressure regulation valve is well-known in this technical field under the names of conductance valve, gate valve or high vacuum valve. The pressure regulation valve is closed at the time of the non-use thereof, and it is opened at the time of the use thereof so as to maintain a predetermined pressure (vacuum state) of the processing chamber 102 which has been provided by the high vacuum pump 106.

As shown in FIG. 1, according to the this embodiment, the high vacuum pump 106 is directly connected to the processing chamber 102. Herein, the “direct connection” means that these members are connected without using a pipe arrangement to be disposed therebetween, but it is possible that a pressure regulation valve is disposed between the high vacuum pump 106 and the processing chamber 102.

In the side wall of the processing chamber 102, there are provided a gas supplying ring 140 made of quartz pipe which is connected to the (reactant) gas supply system 130, and a gas supplying ring 170 made of quartz pipe which is connected to the (discharge) gas supply system 160. The gas supply systems 130 and 160 have gas sources 131 and 161, valves 132 and 162, massflow controllers 134 and 164, and gas supplying flow channels or passages 136 and 166 which connect these corresponding members. The supplying flow channels 136 and 166 are connected to the gas supply rings 140 and 170.

Referring to FIG. 1, in this embodiment, a reactant gas such as C₄F₈ is supplied from a site (nozzle 211) in the neighborhood of the central part of the plasma processing chamber. Specific examples of the reactant gas may include: gases such as CₓF_{y}-type gas (e.g., C₄F₈, and C₅F₈), 3MS (trimethylsilane), and TMCTS (tetramethyl cyclotetrasiloxane). For example, when a Low-k (low-dielectric constant) film such as CFx film is intended to be formed, it is possible to use a combination of (C₄F₈+Ar) gas. It is also possible to supply a gas for plasma excitation from the nozzle 211, in combination with or in a mixture with the above-mentioned reactant gas as desired. In this case, specific examples of the plasma excitation gas may include: inert gases or rare gases such as Ar, He, Kr, and Xe, or gases such as O₂.

For example, when a silicon nitride film is intended to be deposited, the gas source 131 supplies a reactant gas (or raw material gas) such as NH₃ or SiH₄ gas, and the gas source 161 supplies a discharge gas such as either of neon, xenon, argon, helium, radon, and krypton, etc., to which N₂ and H₂ have been added. However, the gas to be used in such a case is not limited to these specific examples, but it is possible to use a gas in a wide range, such as Cl₂, HCl, HF, BF₃, SiF₃, GeH₃, AsH₃, PH₃, C₂H₂, C₃H₈, SF₆, Cl₂, C₂ClF₂, CF₄, H₂S, CCl₄, BCl₃, PCl₃, SiCl₄, and CO.

The gas supply system 160 can be omitted, by using one gas source for supplying a mixture gas comprising gases to be supplied from the gas sources 131 and 161, instead of using the above-mentioned gas source 131. The valves 132 and 162 are controlled so that they are opened at the time of plasma-processing the object W to be processed, and they are closed at the time other than the plasma processing time.

The massflow controllers 134 and 164 control the flow rate of the gas. For example, they has a bridge circuit, an amplifier circuit, a comparator control circuit, a flow rate regulation valve, etc. They control the flow rate regulation valve by detecting the heat transfer from the upstream portion to the downstream portion along with the gas flow so as to measure the flow rate. However, the structure of the massflow controllers 134 and 164 is not particularly limited, but any of other known structures thereof is applicable to those according to the present invention.

The gas supply channels 136 and 166 use, e.g., a seamless pipe, or use an interlocking-type coupling and a metal gasket coupling in the joint portion, so as to prevent the mixing of an impurity from the pipe arrangement to the gas to be supplied therefrom. In order to prevent dust particles due to the contamination or corrosion of the inside of the pipe arrangement, the pipe arrangement is constituted by a corrosion-resistant material, or the inside of the pipe arrangement is provided with an insulating property by using an insulating material such as PTFE (polytetrafluoroethylene, e.g., Teflon (registered trademark)), PFA, polyimide, and PBI; or is subjected to an electrolytic polishing process. Further, the pipe arrangement may have a dust particles capture filter.

As shown in FIG. 4, the gas supplying ring 140 for supplying a gas from the peripheral portion of the processing chamber 102, has a ring-shaped housing or main body comprising quartz, and has an introduction port 141 connected to the gas supplying channel 136, a flow channel 142 connected to the introduction port 141, a plurality of gas introduction pipes 143 connected to the flow channel 142, an outlet port 144 connected to the flow channel 142 and a gas discharge channel 138, and an installation portion 145 for the processing chamber 102. Herein, FIG. 4 is a plan view of the gas supply ring 140.

The plural gas introduction pipes 143 which are uniformly disposed, contribute to the formation of a uniform gas flow in the processing chamber 102. Of course, the gas supply means according to the present invention is not limited to this specific example, but it is possible to use a radial flow method wherein the gas is flown from the central portion to the peripheral portion, or a shower head method (as described hereinafter) wherein the gas is introduced by providing a large number of holes or apertures in a side of the shower head facing the object W to be processed.

As described hereinbelow, the gas supply ring 140 (the flow channel 142 and gas introduction pipe 143 thereof) in this embodiment can be evacuated from the outlet port 144 connected to the gas discharge channel 138. The gas introduction pipe 143 has only a diameter of about 0.1 mm. Accordingly, even when the gas supplying ring 140 is evacuated by using the high vacuum pump 106 through the gas introduction pipe 143, the water content capable of remaining in the inside thereof cannot be removed effectively. From such a viewpoint, the gas supply ring 140 in this embodiment is constituted so that a residue such as water content in the flow channel 142 and the gas introduction pipe 143 can effectively be removed through an outlet port 144 having a aperture larger than that of the nozzle 143.

In addition, in the same manner as in the case of the gas introduction pipe 143, a gas introduction pipe 173 is provided in the gas supply ring 170, and the gas supplying ring 170 has a structure which is the same as or similar to that of the gas supplying ring 140. Therefore, the gas supply ring 170 has an introduction port 171 (not shown), a flow channel 172, a plurality of gas introduction pipes 173, an outlet port 174, and an installation portion 175. In the same manner as in the case of the gas supply ring 140, the gas supply ring 170 (the flow channel 172 and gas introduction pipe 173 thereof) in this embodiment can be evacuated from the outlet port 174 connected to the gas discharge channel 168. The gas introduction pipe 173 has only a diameter of about 0.1 mm. Accordingly, even when the gas supplying ring 170 is evacuated by using the high vacuum pump 106 through the gas introduction pipe 173, the water content capable of remaining in the inside thereof cannot be removed effectively. From such a viewpoint, the gas supply ring 170 in this embodiment is constituted so that a residue such as water content in the flow channel 172 and the gas introduction pipe 173 can effectively be removed through an outlet port 174 having a aperture larger than that of the nozzle 173.

The other end of the gas discharge channel 138 connected to the outlet port 144 of the gas supply ring 140, is connected to a vacuum pump 152 through a pressure regulation valve 151. In addition, the other end of the gas discharge channel 168 connected to the outlet port 174 of the gas supply ring 170, is connected to a vacuum pump 154 through a pressure regulation valve 153. Specific examples of the vacuum pumps 152 and 154 usable in the present invention may include a turbo-molecular pump, a sputter ion pump, a getter pump, an adsorption pump, a cryopump, etc.

The opening and closing timing for the pressure regulation valves 151 and 153 is controlled so that they are closed when the valves 132 and 162 are opened, and are opened when the valves 132 and 162 are closed. As a result, at the time of the plasma processing when valves 132 and 162 are opened, the vacuum pumps 152 and 154 are closed, so that the use of the gas for the plasma processing is ensured. On the other hand, in the period other than the plasma processing wherein the valves 132 and 162 are closed, such as the period after the completion of the plasma processing, the period wherein the object W to be processed is being introduced into the processing chamber 102 or removed therefrom, and the period wherein the susceptor 104 is being moved up and down; the vacuum pumps 152 and 154 are opened. In this manner, the vacuum pumps 152 and 154 respectively evacuate the gas supply rings 140 and 170 to a degree of vacuum at which the influence of the residual gas can substantially be ignored. As a result, the vacuum pumps 152 and 154 can prevent the mixing of a contamination such as water content into the object W to be processed, or ununiform introduction of the gas due to clogging of the gas introduction pipes 143 and 173 in the subsequent plasma processing, so that object W to be processed can be subjected to a high quality processing.

Referring to FIG. 1, the microwave source 110 comprises, e.g., a magnetron, which can generally generate a microwave of 2.45 GHz (e.g., 5 kW). The transmission form or mode of the microwave is subsequently converted into a TM, TE or TEM mode by a mode converter 112. For example, in this embodiment, the transmission form of the TE mode is converted into the TEM mode by the mode converter 112.

In addition, in FIG. 1, an isolator for absorbing the reflected wave corresponding to the return of the generated microwave to the magnetron, and an EH tuner or stub tuner for providing the matching with the load side are omitted.

In the upper part of antenna member 120, as desired, a temperature-controlling plate 122 can be provided. The temperature-controlling plate 122 is connected to a temperature controller 124. For example, the antenna member 120 comprises a slot-type electrode to be described hereinafter. Between the antenna member 120 and the temperature-controlling plate 122, it is possible to dispose a slow-wave material 125 to be described hereinafter, as desired.

A dielectric plate 121 is disposed in the lower part of the antenna member 120. The antenna member 120 and the temperature-controlling plate 122 may be accommodated in a container member (not shown) as desired. As this container member, a material (e.g., stainless steel) having a high thermal conductivity can be used, and the temperature thereof is set to a temperature which is almost the same as the temperature of the temperature-controlling plate 122.

AS the slow-wave material 125, a predetermined material having a predetermined dielectric constant for shortening the wavelength of the microwave, and having a high thermal conductivity is selected. In order to uniformize the density of the plasma to be introduced into the processing chamber 102, it is necessary to form many slits 120a in the antenna member 120. The slow-wave material 125 has a function of enabling the formation of many slits 120a in the antenna member 120. For example, as the slow-wave material 125, it is possible to use alumina-type ceramic, SiN, AlN, etc. For example, AlN has a relative dielectric constant εₜ of about 9, and the wavelength compaction ratio thereof is 1/(εₜ)^{1/2}=0.33. When such an arrangement is adopted, the speed of the microwave which has passed through the slow-wave material 125 becomes 0.33 times, and the wavelength thereof also becomes 0.33 times, and the distance between the slits 120a of the antenna member 120 can be shortened, to thereby enable the formation of a larger number of slits.

The antenna member 120 is screwed to the slow-wave material 125, and comprises, e.g., a cylindrical copper sheet having a diameter of 50 cm and a thickness of 1 mm or less. The antenna member 120 may also be called a radial-line slot antenna (RLSA) or an ultra-high efficiency plane antenna. However, the present invention does not exclude the application of an antenna having another form, such as one-layer structure waveguide plane antenna, and dielectric substrate parallel-plate slot array.

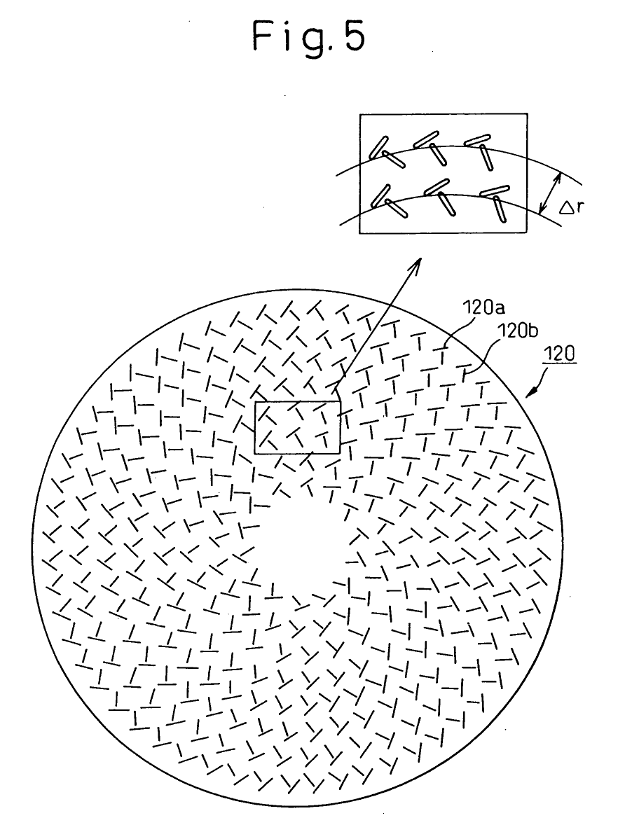

As the antenna member 120, it is possible to use an antenna member 120 as shown in the plan view of FIG. 5. As shown FIG. 5, a plurality of slots 120a, 120a, . . . are formed concentrically on the surface thereof. Each slot 120a comprises a through groove having a substantially rectangular shape. The slots 120a are provided so that the adjacent slots are perpendicular to each other so as to form a configuration similar to an alphabetical character of “T”. The length and the interval of the arrangement of the slots 120a can be determined depending on the wavelength of the microwave which has been generated by the microwave power supply unit 61.

The temperature control 124 has a function of controlling the temperature of a container member (not shown) and a constituent member disposed in the neighborhood thereof so that the temperature change in these members due to the microwave heating is within a predetermined range. The temperature controller 124 connects a temperature sensor and a heater device (not shown) to the temperature-controlling plate 122, and the temperature controller 124 controls the temperature of the temperature-controlling plate 122 to a predetermined temperature, by introducing cooling water or a coolant (such as alcohol, Garden, and Freon) into the temperature-controlling plate 122. For example, the temperature-controlling plate 122 may preferably comprise a material such as stainless steel, which has a good thermal conductivity, and enables the easy formation of a flow channel therein which is capable of flowing cooling water, etc. The temperature-controlling plate 122 comes into contact with the container member (not shown), and the container member (not shown) and the slow-wave material 125 have a high thermal conductivity. As a result, it is possible to control the temperature of the slow-wave material 125 and the antenna member 120 by regulating the temperature of the temperature-controlling plate 122. If none of the temperature-controlling plate 120, etc., is provided, the temperature of the electrode per se is elevated due to the electric power loss in the slow-wave material 125 and the antenna member 120, when a power of the microwave source 110 (e.g., 5 kw) is applied for a long time. As a result, in this case, the slow-wave material 125 and the antenna member 120 can be deformed due to the resultant thermal expansion thereof.

The dielectric plate 121 is disposed between the antenna member 120 and the processing chamber 102. For example, the antenna member 120 and the dielectric plate 121 are face-to-face bonded firmly and intimately by using, e.g., a solder. Alternatively, it is also possible to form, on the back side of the dielectric plate 121 comprising burnt ceramic or aluminum nitride (AlN), a copper thin film which has been provided with a pattern of the antenna member 120 including slits by screen printing, etc., so that the copper foil in the form of the antenna member 120 may be printed on the dielectric plate 121.

In addition, the dielectric plate 121 may also be caused to have a function of the temperature-controlling plate 122. That is, the temperature of the dielectric plate 121 can be controlled by integrally mounting a temperature-controlling plate having a flow channel to a portion in the neighborhood of the periphery of the dielectric plate 121, to thereby control the slow-wave material 125 and the antenna member 120. The dielectric plate 121 is fixed to the processing chamber 102, e.g., by an O-ring. Therefore, alternatively, it is possible to constitute the system such that the temperature of the dielectric plate 121 (and as a result, the temperature of the slow-wave material 125 and the antenna member 120) is controlled by regulating the temperature of the O-ring.

The dielectric plate 121 prevents a phenomenon such that the pressure of the processing chamber 102 in a reduced pressure or vacuum environment is applied onto the antenna member 120 so as to deform the antenna member 120, or the antenna member 120 is exposed to the processing chamber 102 so as to be subjected to sputtering, or to cause copper contamination. In addition, the dielectric plate 121 which is an insulator enables the microwave to transmit to pass into the processing chamber 102. as desired, the dielectric plate 121 may be constituted by a material having a low thermal conductivity, so as to prevent the influence of the temperature of the processing chamber 102 on the antenna member 120.

(Structures of Respective Portions)

Next, there will be specifically described the respective portions constituting the plasma processing apparatus according to the present invention.

(Gas Introduction Pipe)

In the present invention, the gas introduction pipe 211 as shown in FIG. 1 is disposed in a position in the processing chamber which enables the preferred control of the gas dissociation. According to the investigation and experiments by the present inventors, it has been found that the “position in the processing chamber enabling the preferred control of the gas dissociation” (i.e., “height of the projection” d as shown in FIG. 1) may preferably be as follows:

(1) The position corresponding to an electron temperature of 1.6 eV or less of the plasma to be generated,

(2) The position such that the height d is larger than the penetration length of a high frequency electric field of the plasma to be generated.

The height d of the projection may preferably be 1.02 times or more, more preferably 1.05 times or more, more preferably 1.1 times or more, particularly 1.2 times or more the penetration length δ.

In general, when the electron density in the plasma exceeds the cut-off density, and a relationship of ωₚₑ>ω is satisfied, the high frequency cannot to propagate in the plasma, and it is reflected in the neighborhood of the surface thereof. Herein, ωₚₑ is an electronic plasma frequency represented by the formula:

ωₚₑ=(e²nₑ/ε₀mₑ)^{1/2},

wherein ω denotes the angular frequency of the high frequency, “e” denotes the charge of electron, ε₀ denotes the dielectric constant of vacuum, and me denotes the mass of electron. The electric field and the magnetic field of the high frequency which is incident in the z-direction will penetrate into the plasma so as to provide an amplitude which is proportional to exp(−z/δ), while being decreased exponentially. Herein, the penetration length δ is represented by the following formula:

δ=c/(107 ₚₑ²−ω²)^{1/2}

wherein “c” denotes the velocity of light.

On the other hand, the value of d may preferably be one such that it corresponds to a distance between the gas introduction pipe and the object to be processed of 5 mm or more, more preferably 10 mm or more, particularly 15 mm or more.

As desired, the height d may be variable. The means for making the d variable is not particularly limited, but it is preferred to use a combination of (a motor and bellows), or a combination of (a motor and an O-ring).

The means for making this value d variable may be at least one of electric means, mechanical means, or manual means. Further, the value d may be variable continuously or in a step-by-step or stepwise manner. For example, it is possible to use a member (such as nozzle) having one of different lengths for providing a suitable value of d may be disposed so that it is movable and/or removable (or detachable) by electric, mechanical and/or manual means.

(Case Based on Electron Temperature of Plasma)

In the present invention, the “height of the projection” d may preferably be a position corresponding to an electron temperature of 1.6 ev or less of the plasma to be generated. The height of the projection d may more preferably be a position corresponding to an electron temperature of 1.5 ev or less, preferably 1.4 eV or less, more preferably 1.3 ev or less, particularly 1.2 ev or less.

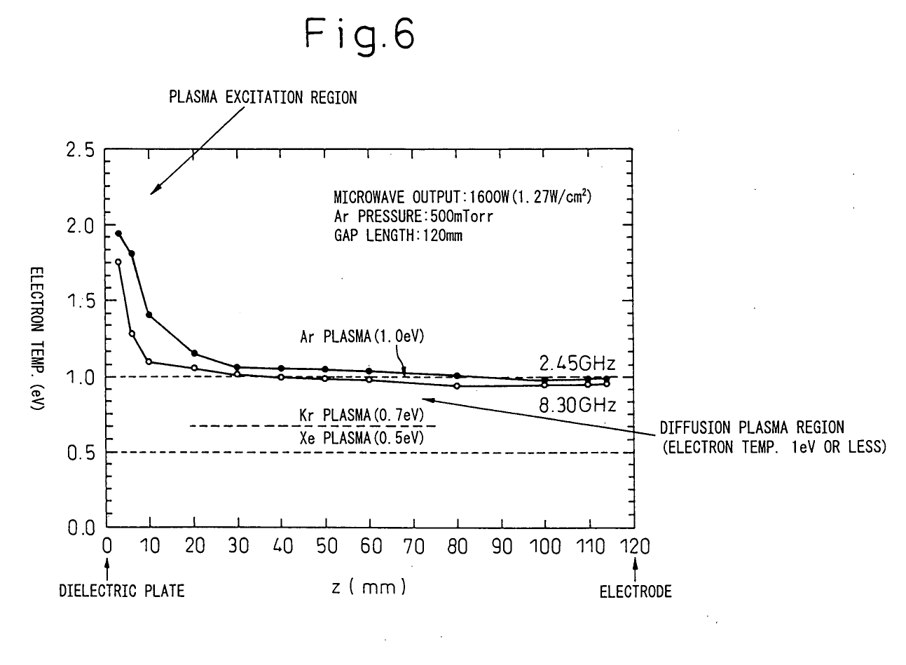

FIG. 6 is a graph showing an example of the relationship between the distance (z) from the dielectric plate in a high density plasma based on microwave excitation, and the electron temperature of the plasma. When a plasma having the relationship between the distance and the electron temperature as shown in this graph is used, the position corresponding to the electron temperature of 1.2 eV or less of the plasma corresponds to the position of z=20 mm or more.

In addition, the preferred “height of the projection” d may be represented by the position of the plasma electron temperature which is 1.6 times or less the electron temperature (Tₑₛ) to be used for the plasma processing of the object to be processed (such as wafer). The “height of the projection” d may more preferably be the position corresponding to 1.4 times or less, more preferably 1.2 times or less the Tₑₛ. For example, in the case of the graph of FIG. 6, when the object to be processed (such as wafer) is disposed at a position corresponding to an electron temperature of 1.0 ev, the “height of the projection” d may preferably be a position corresponding to an electron temperature of 1.6 eV or less.

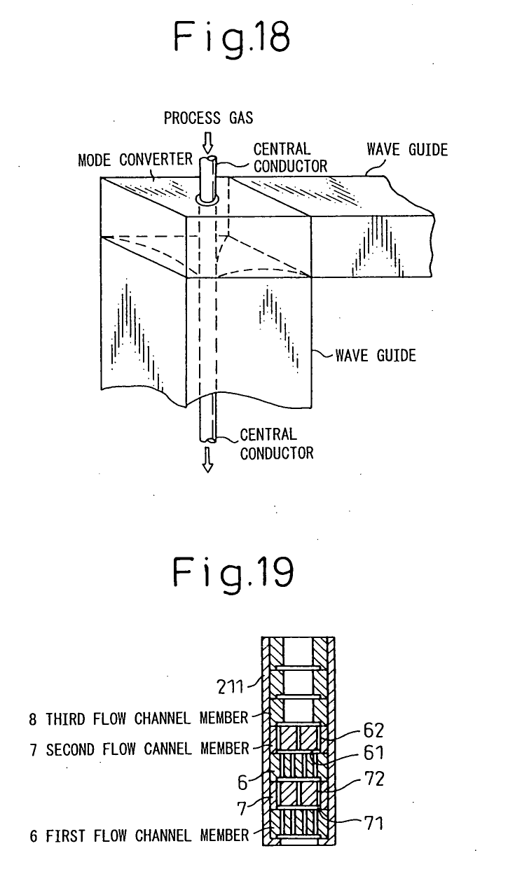

The schematic perspective view of FIG. 18 shows an embodiment of the arrangement of the waveguide, the coaxial tube (which is in the form of a mode converter in the embodiment of FIG. 18), and the central conductor for introducing a process gas, which are usable in the present invention. In the embodiment as shown in FIG. 18, the inside of the central conductor of the coaxial waveguide constituting a mode converter is formed into a hollow-type, and the hollow coaxial waveguide is constituted so that the central conductor of the coaxial waveguide is caused to have a function of a gas flow channel for flowing a process gas.

(Gas Supply Means)

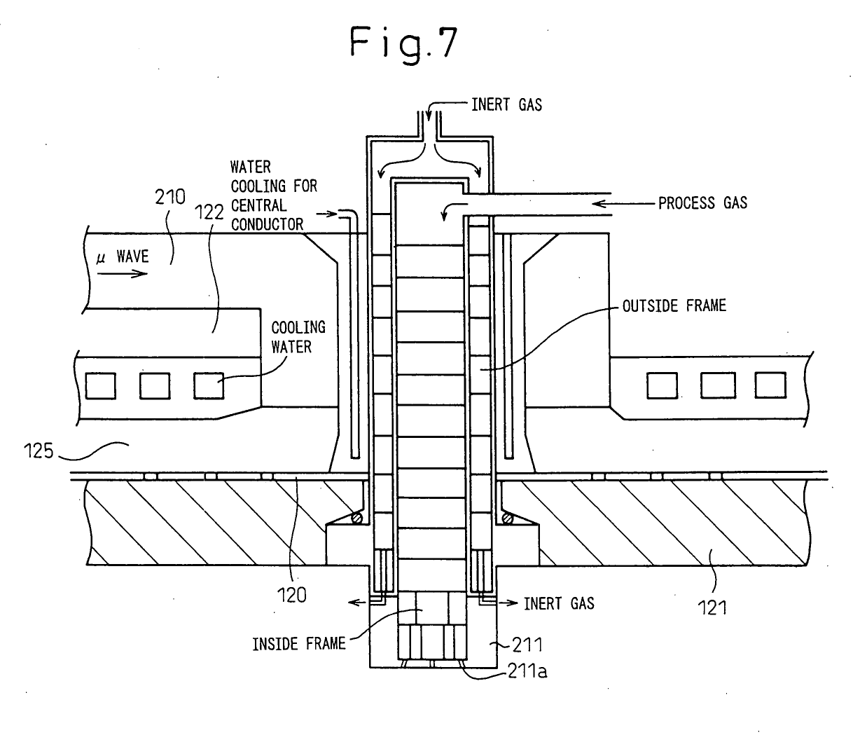

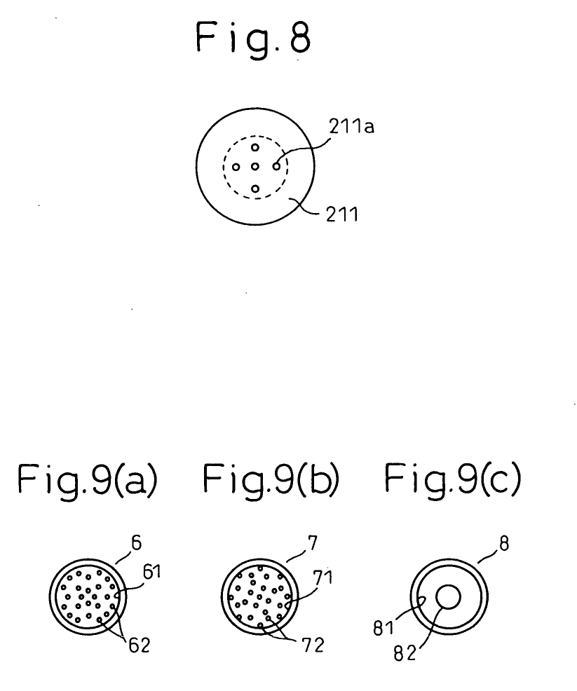

The partial schematic sectional view of FIG. 7 shows another example of the gas supply means which is usable in the present invention. The schematic plan view of FIG. 8 shows an example of the shape of a gas outlet opening (or aperture), when the gas supply means as shown in this FIG. 7 is used.

Referring to FIG. 7, in the embodiment of such gas supply means, not only a reactant gas or process gas (CₓF_{y} in this example), but also an inert gas (such as Ar and He) is supplied from a site in the neighborhood of the central part of the plasma processing chamber into the plasma processing chamber. The diameter of the gas outlet hole as shown in FIG. 8 may preferably be a diameter which is less liable to cause abnormal discharge of the plasma. More specifically, the diameter may preferably be about φ=0.5 mm to 0.3 mm.

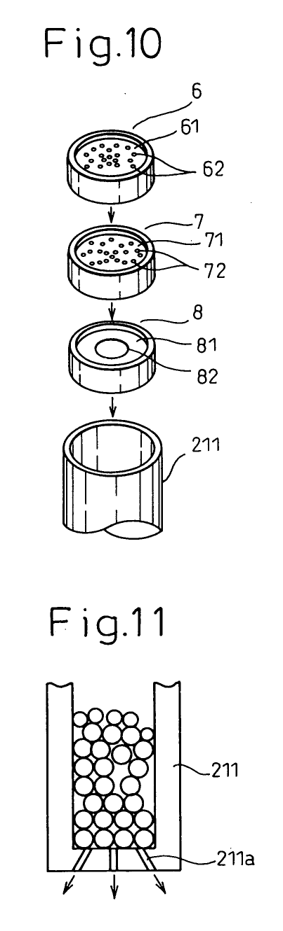

In FIG. 7, a first flow channel member 6, a second flow channel member 7, and a third flow channel member 8 as shown in the schematic plan view in FIG. 9, are arranged in a manner as shown in the schematic perspective view showing FIG. 10., and are disposed in the gas introduction pipe (in this example, in the central conductor). Hereinbelow, such a flow channel member is sometimes referred to as “frame”. In this way, the abnormal discharge of the plasma based on a high frequency can more effectively be prevented by thinning the individual gas flow channel.

The first flow channel member 6 and the second flow channel member 7 may be constituted by machining an insulating material such as Teflon, into a cylindrical shape. In such a case, the first flow channel member 6 and the second flow channel member 7 may have an indentation portion 61 or 71 on one end thereof, which has a diameter slightly smaller than the outside diameter thereof, and has a depth of, e.g., about 1 mm, and a large number of conduction flow holes 62 or 72 having a small diameter of, e.g., 1 mm or less, which are provided in the axis direction of the first flow channel member 6 and the second flow channel member 7 from the bottom face thereof having the above indentation portion 61 or 71 toward the other face of the first flow channel member 6 and the second flow channel member 7.

The schematic sectional view of FIG. 19 shows another arrangement of the first, second and third flow channel members which are usable in the present invention. This example as shown in this FIG. 19 also corresponds to that structure of the flow channel members as shown in FIG. 9 and FIG. 10.

(Use of Porous Ceramic)

The flow channel member may also be constituted by using a porous ceramic, instead of using a flow channel member wherein the above-mentioned holes have been formed. In this case, preferred examples of the ceramic may include: alumina (Al₂O₃), quartz, AlN, etc. For example, the porous ceramic may preferably be one having an average pore size of about 1.5-40 μm, and a porosity of about 30-50%. Preferred examples of the commercially available product may include: alumina ceramic having a trade name FA-4 (average pore size of 40 μm), and FA-10 (average pore size 1.5 μm) both mfd. by Kyocera Co.

(Use of Balls)

As shown in the schematic sectional view of FIG. 11, the flow channel member may also be constituted by using balls (or beads) made of ceramic, instead of using the above-mentioned flow channel member. In this case, preferred examples of the ceramic may include: alumina (Al₂O₃), quartz, AlN, etc. For example, the balls may preferably be those having a diameter of about 0.5-3 mm. In FIG. 11, a gas outlet 211a extending downward is provided in the gas introduction pipe 211.

(Embodiment of Gas Blowing)

In the present invention, the kind of the gas, one kind or plural kinds of the gases, etc., are not particularly limited, as long as at least one kind of the gas is supplied from the site projecting into the plasma processing chamber. When plural kinds of gases are supplied into the plasma processing chamber, either one kind of the gas, either two kinds of the gases, or all of the gases can be supplied into the plasma processing chamber from the site in the neighborhood of the central part of the plasma processing chamber. In view of the exhibition of an advantageous effect of the present invention, it is preferred to supply a gas having a predominant influence on the uniformity of the plasma processing (such as those so-called “reactant gas” or “process gas”) from the site in the neighborhood of the central part of the plasma processing chamber.

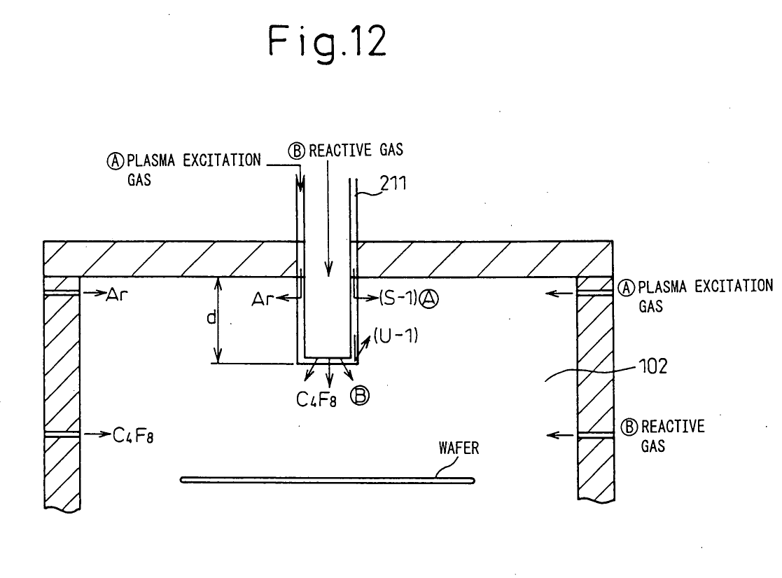

FIG. 12 schematically shows an embodiment of the gas supply method which is suitably usable in the present invention.

Referring to FIG. 12, in this embodiment, an inert gas (A) for the plasma excitation such as argon, and a reactant gas such as C₄F₈ are supplied from the site in the neighborhood of the central part of the plasma processing chamber. Specific examples of the plasma excitation gas (A) may include: inert gases or rare gases such as Ar, He, Kr, and Xe; and a gas such as O₂. On the other hand, specific examples of the process reactive gas (B) may include gases such as CₓF_{y}-type gas (such as C₄F₈, and C₅F₈), 3MS (trimethylsilane), TMCTS (tetramethyl cyclotetrasiloxane), etc. For example, when a Low-k (low-dielectric constant) film such as CFx film is intended to be formed, it is possible to use a combination of (C₄F₈+Ar) gas. It is also possible to supply the gas (A) for the plasma excitation and/or the process reactive gas (B) as desired, from a peripheral portion of the plasma processing chamber as shown in FIG. 12.

It is also possible to pour the gas (A) for the plasma excitation so that it is directed laterally in a region having a high electron temperature as shown by the reference (S-1) in FIG. 12, or to pour the gas (A) for the plasma excitation so that it is directed upward in a region having a low electron temperature as shown by the reference (U-1) in FIG. 12. On the other hand, as shown in FIG. 12, the process reactive gas (B) may preferably be poured from the position in the processing chamber capable of providing a preferred plasma dissociative state, downward, laterally, or obliquely downward.

(Examples of Specific Structure of Outlet)

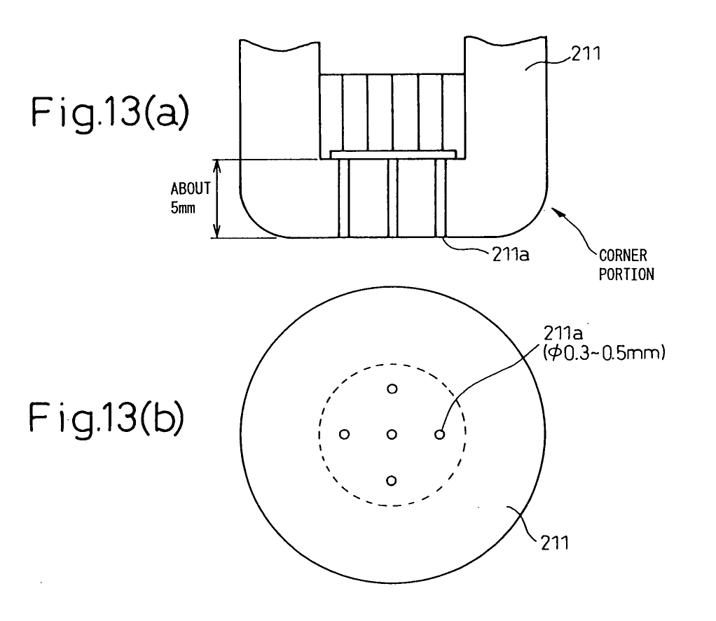

The partial schematic sectional view of FIG. 13 shows an example of the specific structure or arrangement, when the gas is poured in the right below from the gas introduction pipe 211. In this case, as shown in FIG. 13(a), the corner portion of the gas introduction pipe 211 may preferably be rounded, in view of the effective prevention of an abnormal discharge.

In this embodiment, as shown in FIG. 13B, there are provided five straight holes 211a (i.e., extending in the right below direction). In order to suppress the abnormal discharge, the hole 211a may preferably have a diameter of, e.g., about 0.1-0.5 mm φ diameter. In addition, the length of the hole 211a may preferably be about 1-5 mm (e.g., about 5 mm).

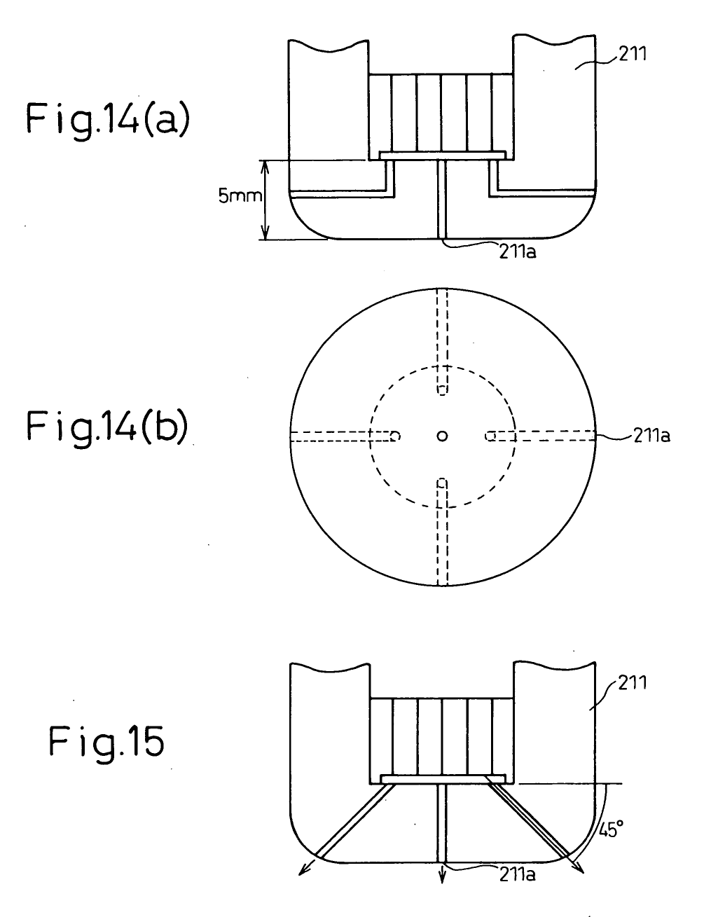

The partial schematic sectional view of FIG. 14 shows an example of the specific structure or arrangement, when the gas is in the poured right below direction and in the lateral direction from the gas introduction pipe 211. For example, the gas introduction pipe 211 may preferably be constituted by alumina (Al₂O₃), AlN, etc.

In this case, as shown in FIG. 14(a), the corner portion of the gas introduction pipe 211 may preferably be rounded, in view of the effective prevention of an abnormal discharge.

In this embodiment, as shown in FIG. 14(b), there are provided one straight (i.e., extending in the right below direction) hole 211a, and four holes 211a extending in the lateral direction. In order to suppress the abnormal discharge, the hole 211a may preferably have a diameter of, e.g., about 0.1-0.5 mm φ diameter. In addition, the length of the straight hole 211a may preferably be about 1-5 mm (e.g., about 5 mm).

The partial schematic sectional view of FIG. 15 shows an example which uses a hole 211a extending in a downward oblique (or diagonal) direction, instead of using a hole 211a extending in the lateral direction as shown in FIG. 14. The angle corresponding to the obliqueness in this case can arbitrarily be determined, but the angle may preferably be, e.g., about 45° as shown in FIG. 15.

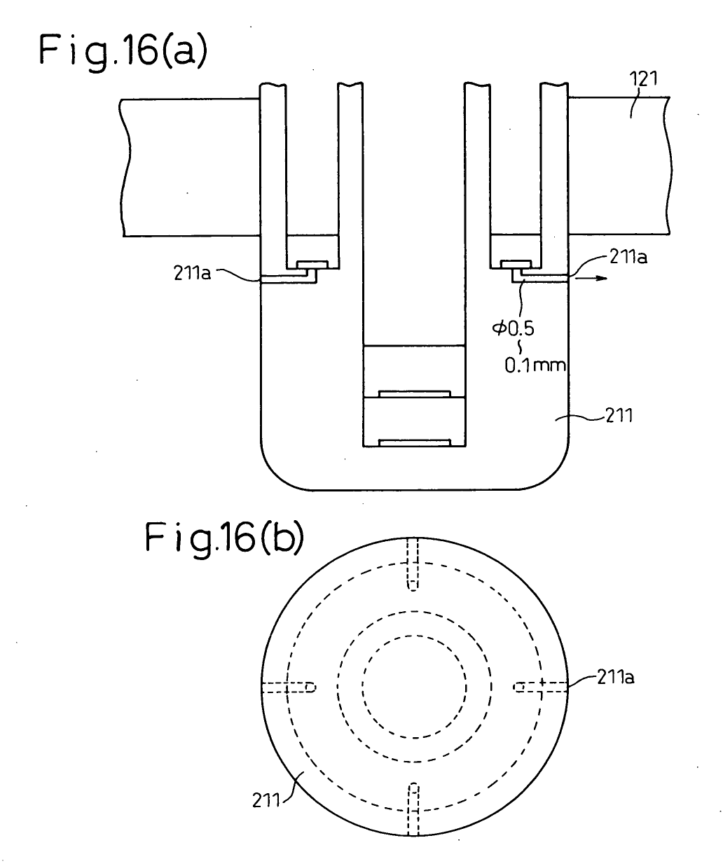

The partial schematic sectional view of FIG. 16 shows an example of the specific structure or arrangement wherein the outlet of the outside gas (e.g., plasma excitation gas) to be supplied from the gas introduction pipe 211 is disposed in the position right below the dielectric plate. In this case, as shown in FIG. 16(a), the hole 211a may preferably have a diameter of, e.g., about 0.1-0.5 mm φ diameter.

FIG. 16(b) shows an example of the arrangement wherein four holes 211a are disposed in the lateral direction. However, the number of the holes 211a may also be any number of three or more (e.g., four or eight).

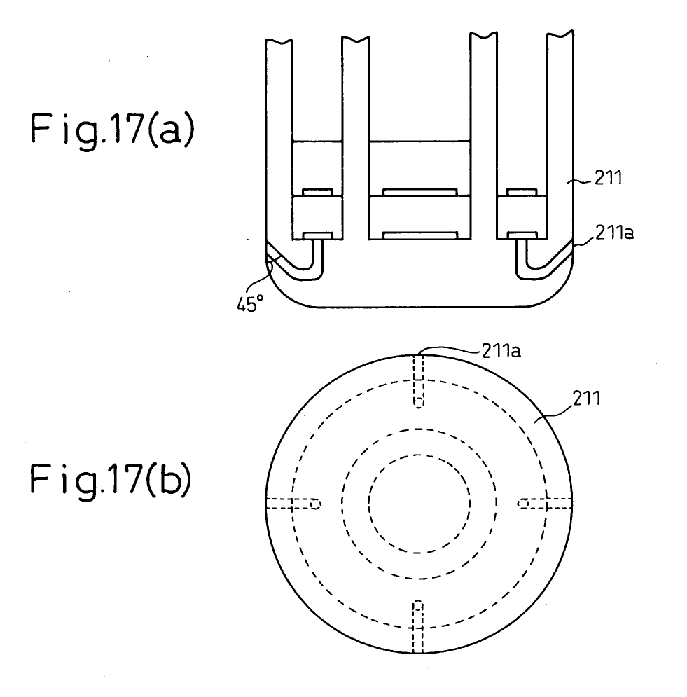

The partial schematic sectional view of FIG. 17 shows an example of the specific structure or arrangement wherein the outlet of the outside gas (e.g., plasma excitation gas) to be supplied from the gas introduction pipe 211 is disposed in the lowermost position. In this case, as shown in FIG. 17(a), the hole 211a may preferably be disposed so as to extend upward (e.g., at an angle of 45°), for example. FIG. 17(b) shows an example of the arrangement wherein four holes 211a are disposed in the upward direction. However, the number of the holes 211a may also be any number of three or more (e.g., four or eight).

(Plasma-Generating Means)

In the above-mentioned respective embodiments according to the present invention, there have been mainly explained some examples using a so-called plane antenna member. However, the plasma-generating means usable in the present invention is not particularly limited, as long as it enables the plasma excitation based on a gas which has been supplied from a site in the neighborhood of the central portion of the plasma processing chamber. Specific examples of the plasma-generating means usable in the present invention may include: ICP (inductively coupled plasma), spoke-type antenna, microwave plasma, etc. In the present invention, the above-mentioned plane antenna member may preferably be used, in view of the uniformity, density, and relatively low electron temperature (which is capable of providing little damage on the object to be processed) in the plasma to be generated.

### INDUSTRIAL APPLICABILITY

As described hereinabove, according to the present invention, it becomes easy to supply a gas to a position which is suitable for the control of a gas dissociative state. Accordingly, the present invention provides a plasma processing apparatus and a plasma processing method which can improve the uniformity in the composition and/or density of the gas to be supplied for the plasma processing, while controlling the gas dissociative state based on the plasma.

1. A plasma processing apparatus, comprising: at least,
a processing chamber for plasma-processing an object to be processed;
gas supply means for supplying a gas into the processing chamber; and
high-frequency supplying means for forming the gas into a plasma state;
wherein the gas supply means has at least one gas introduction pipe, the tip of the gas introduction pipe is placed in a position so that the tip is projected from the inner wall of the processing chamber facing the object to be processed, toward the interior of the processing chamber.

2. A plasma processing apparatus according to claim 1, wherein the position of the tip of the gas introduction pipe is within the diffusion plasma region of the plasma to be generated.

3. A plasma processing apparatus according to claim 1 or 2, wherein the position of the tip of the gas introduction pipe corresponds to the position providing a electron temperature of 1.6 ev or less.

4. A plasma processing apparatus according to any of claims 1-3, wherein the position of the tip of the gas introduction pipe corresponds to the position providing a plasma electron temperature which is 1.6 times or less the plasma electron temperature (Tes) to be used for the plasma processing of the object to be processed.

5. A plasma processing apparatus according to any of claims 1-4, wherein the position of the tip of the gas introduction pipe corresponds to the position exceeding the high frequency penetration length δ of the plasma to be generated.

6. A plasma processing apparatus according to any of claims 1-5, wherein the tip of the gas introduction pipe is projected into the interior of the processing chamber so as to provide a projecting height of 5 mm or more.

7. A plasma processing apparatus according to any of claims 1-6, wherein a high frequency is supplied into the processing chamber from the high-frequency supplying means through a plane antenna member having a plurality of slots.

8. A plasma processing apparatus according to any of claims 1-7, wherein the high-frequency supplying means includes a coaxial tube, and the central conductor constituting the coaxial tube is the gas introduction pipe.

9. A plasma processing apparatus according to any of claims 1-8, wherein plural kinds of gases are supplied from the gas introduction pipe into the processing chamber.

10. A plasma processing apparatus according to claim 9, wherein the plural kinds of gases comprise a plasma excitation gas and a reactant gas for the plasma processing.

11. A plasma processing apparatus according to any of claims 1-10 wherein the gas is also supplied into the processing chamber from a peripheral portion of the processing chamber.

12. A plasma processing apparatus according to any of claims 1-11, wherein the projection height of the tip of the gas introduction pipe into the processing chamber is variable.

13. A plasma processing apparatus according to any of claims 1-12, wherein a flow channel member is disposed in at least one portion of the gas introduction pipe

14. A plasma processing method, wherein an object to be processed which is placed in a processing chamber is subjected to plasma processing by utilizing plasma based on a gas which has been supplied into the processing chamber; the gas being supplied into the processing chamber from a gas introduction pipe; the tip of the gas introduction pipe being projected from the inner wall of the processing chamber facing the object to be processed, toward the interior of the processing chamber.

15. A plasma processing method according to claim 14, wherein the plasma processing of the object to be processed is at least one selected from the group consisting of: etching, film formation, cleaning for the object to be processed and/or processing chamber; and ashing for the object to be processed.
